(19) United States
(12) Patent Application Publication
(10) Pub. No.: US 2020/0280169 A1
(43) Pub. Date: Sep. 3, 2020

(54) Laser Calibration System

(71) Applicants: Stephen Blazo, Corvallis, OR (US); Jeremy Colson, Corvallis, OR (US); Brian Tostberg, Corvallis, OR (US)

(72) Inventors: Stephen Blazo, Corvallis, OR (US); Jeremy Colson, Corvallis, OR (US); Brian Tostberg, Corvallis, OR (US)

(73) Assignee: Wavelength References, Inc., Corvallis, OR (US)

(21) Appl. No.: 16/288,281

(22) Filed: Feb. 28, 2019

(51) Int. Cl. H01S 5/068; H01S 5/06; H01S 5/125; H01S 5/026

(52) U.S. Cl. CPC H01S 5/068; H01S 5/026; H01S 5/125; H01S 5/0617

(57) ABSTRACT

A laser calibration scheme comprising a tunable laser and a means of generating wavelength fiducial markers such as a gas absorption reference cell. The output wavelengths of the laser can be described by a set of one or more continuous functions of its tuning signals. The tuning signals across continous wavelength regions of the laser are measured and stored in a lookup table in memory. To target a desired wavelength, the laser first stabilizes to a gas absorption line in close proximity to the desired wavelength. A correction factor is generated by comparing the resulting tuning signals to those previously derived and stored on the lookup table. For the desired wavelength, a set of tuning signals is interpolated from the lookup table and the correction factor is applied to achieve a calibrated output.

### CROSS REFERENCE TO RELATED APPLICATIONS

Not applicable

### BACKGROUND OF THE INVENTION

Tunable lasers find applications in spectroscopy and optical communications among others. The required accuracy of the emitted wavelength varies with application but can be quite severe. One such application is a laser in a test bed for optical components or optical communication systems. Here ancillary equipment such as a wavelength meter can be used to verify wavelength accuracy. This adds to the expense and complexity of the test system. The wavelength meter or other equipment must also be periodically calibrated to maintain traceability of the test station. Another application is in a DWDM (dense wavelength division multiplexing) optical communication network itself. Here signals from many lasers share a given fiber each spaced at precise wavelength values. The wavelength of each signal must be precisely set so that signals do not interfere with one another. In this case ancillary equipment is normally not available and the tunable laser itself is required to have high accuracy.

The wavelength of a semiconductor tunable laser is controlled by one or more tuning signals. DFB (distributed feedback) semi-conductor lasers can be tuned by temperature over a band of 3-4 nm and by drive current over a smaller range. These are widely used in fiber communication networks. More recently widely tunable semiconductor lasers have become available. One type uses an array of DFB laser chips in one package. One example of this is the Fitel FRL15TCWBV. This device comprises 12 DFB laser chips in a package along with monitoring and temperature control means. At a given time one laser chip that has a tuning range containing the desired wavelength is activated. Each laser chip is only tunable over a small range but together 12 of them in one package can tune over a 35-40 nm range. Another common type is the monolithically constructed semiconductor laser having several segments in the semiconductor. These segments serve as adjustable cavity mirrors, gain regions, and phase regions. One example is the. SG-DBR (sampled grating distributed Bragg reflector) laser. This type uses three or more electrical tuning signals to achieve a particular wavelength along with temperature stabilization. Examples of this type are the Lumentum 6205 and the NeoPhotonics micro-ITLA laser.

For all these types, at the factory, the tuning signals required to generate a particular wavelength are measured and stored for use in the field. This is usually as a lookup table of the required tuning signals required to achieve the wavelength of DWDM channels. It is clear that interpolation or extrapolation can be used to derive tuning signals for wavelengths not exactly measured. The shape of the tuning signals could also be fitted to curves by various well known means.

Environmental conditions or aging can affect the exact values of the tuning signals to achieve a desired wavelength after the initial factory measurement. For example the Fitel laser specifies long term wavelength accuracy of ±20 pm and the Lumentum 6205±14 pm. In DWDM networks channel spacing of 50 GHZ (400 pm) or even 25 GHZ (200 pm) are common. A drift of 20 pm in the central wavelength of a particular channel can affect crosstalk producing transmission errors.

Various means have been used to hold the wavelength more accurately than that provided by the tuning signals alone. This often takes the form of splitting the output and passing this through a temperature controlled etalon. Often the etalon is fabricated with an accurate free spectral range (FSR) that is equal to the channel spacing in the DWDM network. The long term accuracy of a system like this is better than just using the tuning signal lookup table of the laser drive signals alone. Many different configurations on this basic form have been tried in the past and a wavelength locker using this general approach is included in many products including, for example, the Fitel FRL15T. The long term accuracy of this approach is limited, however, due to mechanical drift and various environmental effects. These effects still limit the accuracy of this approach which achieves in the Fitel FRL15T the 20 pm accuracy specification.

To overcome the fabrication and long term accuracy limitations the use of molecular absorption lines of a gas have been employed. Gas absorption lines are known for very high stability and provide for traceability to unvarying physical constants. NIST has promoted this approach and offers several SRMs (Standard Reference Materials) for this purpose. Siddiqui and Lepley in U.S. Pat. No. 6,163,555 describe a system where an etalon is aligned using two lasers, each laser being locked to a specific absorption line of a gas. This filter alignment provides an optical filter whose transmission value is in principle known for all wavelengths. Each laser in an optical network is then periodically compared to the optical filter and the wavelength controlled to the appropriate transmission value. This system is very complex and expensive to implement requiring two additional lasers along with a temperature controlled filter in addition to the laser(s) being stabilized to the gas lines.

What is needed is a practical tunable laser that can span the wavelength range of optical networks that can output an accurate wavelength over time and environment.

### BRIEF SUMMARY OF THE INVENTION

The invention comprises a tunable laser and a gas absorption cell which has absorption lines spaced throughout the wavelength range of the laser. At the initial calibration the tuning signals required to output a given wavelength are measured and stored in memory either as a look up table or fitted to an appropriate function. The invention uses a two stage process to output a desired wavelength. First an absorption line feature is identified in close proximity to the desired wavelength and the laser frequency locked to this feature. The tuning signals required for this lock are measured and compared to those found during the initial calibration. The difference, which will be due to environment or aging, is used to correct the tuning signals derived from the look up table for the desired wavelength and the laser tuned to those corrected values.

### BRIEF DESCRIPTION OF THE DRAWINGS

FIG. 1: Shows a block diagram of the invention

FIG. 2: Shows the wavelength versus tuning signal for a tunable laser

### DETAILED DESCRIPTION OF THE INVENTION

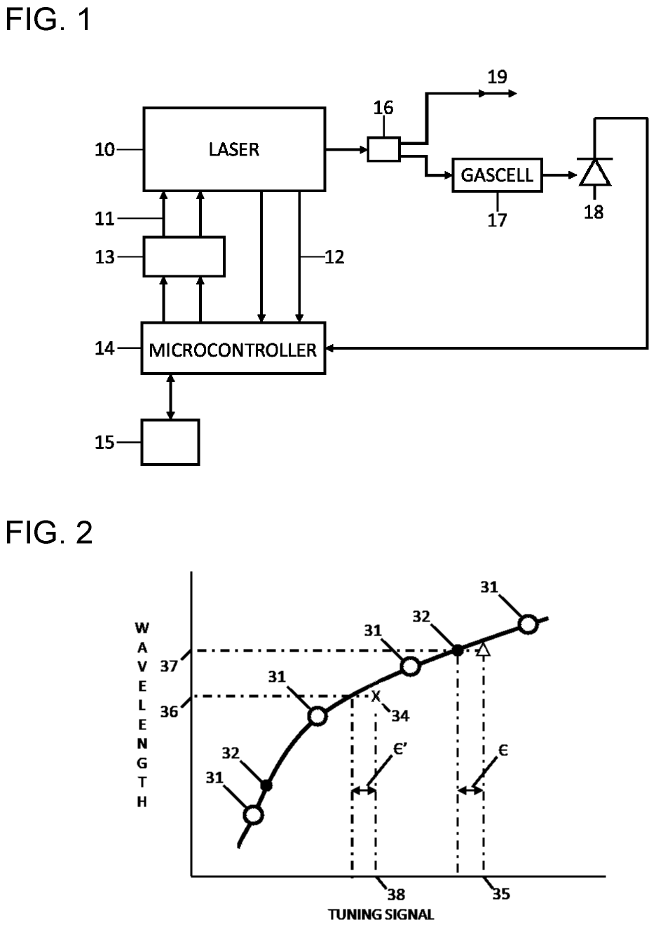

Refer now to FIG. 1. A laser 10 emits a light beam whose wavelength is determined by a set of one or more tuning signal 11. The laser has regions that are continuous functions of the tuning signals. These continuous regions are not necessarily the entire wavelength range of the laser but the entire range of the laser is comprised by a set of one or more continuous regions. The control signals are generated by a microcontroller 14, through a laser drive circuit 13. The controller also receives signals 12 that measure states such as the laser chip temperature, ambient temperature, and output power. The laser output is split by splitter 16. Part of the output signal is passed through a gas cell 17 which is converted to an electrical signal by means of a photodetector 18 and passed to the controller. The rest of the signal is available as useful output 19. The wavelength produced by the control signals is determined in an initial calibration step. This measurement is done with sufficient resolution that the initial precise functional form of the relationship between output wavelength and control signal is known. This data is stored in memory 15 often as a grid of closely spaced values along with the environmental conditions at the time of calibration. If the total range of the laser consists of several discrete discontinuous regions of continuous tuning the measurements are made for each region. Also stored is information on the change in wavelength with ambient temperature if necessary. All this aside from the presence of the gas cell is similar to that provided already by many manufacturers.

The gas cell is chosen so that it presents many absorption lines throughout the wavelength range of the tunable laser. If the laser has several separate continuous ranges of tuning that together comprise the total tuning range the gas cell has at least one line within each continuous tuning segment. For the C-band the C13 HCN cell is just about perfect. For an L-band device carbon monoxide can be used. Within the full C-band the C13 HCN absorption lines are spaced so that the maximum distance from an arbitrary wavelength is <0.5 nm. The gas cell wavelengths do not exhibit aging and almost negligible effect of environmental conditions such as temperature. The Fitel DFB array tunable laser has a individual continuous tuning regions that each span about 3.5 nm and each contain multiple absorption lines.

In the field the response of laser wavelength vs tuning signals can change. This can be the effect of aging of the DFB laser chip itself or that of aging of the thermistor used to set the laser temperature. The laser wavelength is a strong function of the chip temperature typically about 90 pm per degC change. Thus very small changes in the thermistor sensor can have a large effect. Together these effects limit long term wavelength accuracy specifications. The proposed invention eliminates these errors.

The process to reduce wavelength errors using the invention can be summarized: first, lock the laser to a nearby gas line from the desired output wavelength; second, interrogate the tuning signals necessary for lock and compare the tuning signals to that found in the initial calibration data for this gas line wavelength; third, using the change to these tuning signals, derive the appropriate change to the tuning signal calculated for the desired wavelength from the calibration data; and finally, lock the laser to these corrected tuning signals. Changes in ambient temperature can also have a second order effect on the tuning signals necessary to keep the laser at a desired wavelength. This can sensed by temperature sensor for example a thermistor placed in the enclosure somewhere near the laser itself. This can introduce varying time constants that diminish the effectiveness of the temperature compensation. It has been found that to achieve the best ambient temperature compensation the temperature is best sensed by a sensor built into the laser package but separate from the laser chip itself. The temperature is noted at the initial setting to a particular wavelength and any subsequent change in temperature noted with an appropriate change in tuning signals applied to compensate for this.

This process is illustrated on FIG. 2 which shows the tuning signals and the resulting wavelength produced in a sample continuous tuning range. For the Fitel DFB array the main tuning means is via the laser chip temperature which is sensed by a built in thermistor. Secondary tuning is available via the laser drive current. Other devices such as the SG-DBR laser will have other tuning and sensing means but all types can be summarized as a one dimensional path through the perhaps multidimensional tuning space within each separate continuous tuning range. The initial calibration data are shown as points 31. Gas line points 32 are either measured directly during calibration or interpolated from a dense enough set of measurements 31. The desired wavelength is shown as 36. The nearest gas line to this value is shown as 37. The laser is initially locked to this nearest gas line by means of the signal from the gas cell. This results in a tuning signal 35 that differs from the initial calibration data by [symbol] . This difference is used to calibrate the tuning signal for the desired wavelength which will differ from the calibration value by [symbol] ′. [symbol] ′ may not necessarily be exactly the same as [symbol] due to a known curvature to the wavelength versus tuning voltage curve. The curvature of the calibration graph can be used for this purpose if significant. The laser is then set to this calibrated tuning signal 38. Often this tuning signal is the chip temperature which is sensed by a thermistor within the laser package but for reasons stated can experience some long term drift or be affected by environmental conditions such as room temperature. The technique outlined eliminates both effects at least initially. For a single longer term lock the change in ambient conditions can be used to track out second order errors caused by this by using the sensitivity of wavelength to ambient measured in the initial calibration step.

What is claimed is:

1) A calibration apparatus comprising a tunable laser with continuous tuning ranges spanning the total wavelength range, a gas cell which has at least one absorption line in each continuous tuning range, and a map of tuning signals versus wavelength in an initial calibration step for each continuous range wherein when the laser is required to output a particular wavelength the laser is first initially locked to a nearby gas line and the change in tuning signals required to achieve that lock measured and this data is used to generate a correction to the tuning signals for the desired wavelength.

2) The apparatus according to claim 1 where an ambient temperature sensor is built into the laser package itself.

3) The apparatus according to claim 2 wherein the laser is a DFB array.

4) The apparatus according to claim 1 wherein the laser is a monolithically constructed semiconductor laser.
